(19) United States
(12) Patent Application Publication
(10) Pub. No.: US 2003/0141893 A1
(43) Pub. Date: Jul. 31, 2003

(54) PIECEWISE LINEAR SLEW RATE CONTROL OF METHOD FOR OUTPUT DEVICES

(76) Inventor: Jason Gonzalez, Ft. Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/060,133

(22) Filed: Jan. 30, 2002

(51) Int. Cl. H03K 19/003

(52) U.S. Cl. 326/26

(57) ABSTRACT

A novel method and apparatus is presented for reducing the slew rate signals on transmission lines of integrated circuits. When a transmission line is to be driven to a state by a driver device, the voltage on predrive line controlling the driver device is pulled to a level at or very near to the turn-on threshold voltage the driver device, much more quickly than the turn-on setup time of the driver device. A programmed impedance is then connected between an “on” voltage source and the predrive line to result in a controlled slope of the transmission line signal. Once the voltage level on the transmission line reaches a predetermined reference voltage (e.g., the saturation voltage of the driver device, the predrive line is quickly pulled to the “on” voltage level.

### FIELD OF THE INVENTION

The present invention relates generally to integrated circuits, and more particularly to a method for controlling the slew rate of output drivers.

### BACKGROUND OF THE INVENTION

As integrated circuit bus speeds continue to increase, system designers are faced with transmission line issues previously relegated to the analog world. At very high speeds, pc-board traces behave like transmission lines, and reflections occur at all points on the pc-board trace where impedance mismatches exist.

The transition between digital states does not occur instantaneously, but instead occurs over a period of time that is dependent on the physical conditions present on the transmission line. It is well known that signal transitions over a transmission line will suffer a delay known as a propagation delay due to the parasitic resistance, inductance, and capacitance of the line. This delay increases with the length of the line. In addition, it is also well-known that unless the impedance of the transmission line matches that of the load it drives, the signal will degrade due to reflections caused by impedance mismatching.

Signal reflections produce or contribute to a number of problems, including false triggering in clock lines, erroneous bits on data, address, and control lines, clock and signal jitter, and an increase in total emissions from the pc board. One method of reducing these transmission-line effects is to properly terminate the lines. This is especially true when the driver circuit drives multiple loads with differing impedances, the transmission line requires multiple stubs to properly match each of the loads during realtime operation. However, the use of multiple stubs then generates multiple reflections. One way of ensuring proper detection of signal states is to slow the slew rates of the signal's transitioning edges.

However, this competes with the trend towards ever increasing signal frequencies, which results in higher edge rates. Accordingly, a need exists for a technique for controlling the slew rate of signal edge transitions without sacrificing the signal frequency.

### SUMMARY OF THE INVENTION

The present invention is a method and circuit for controlling the slew rate of integrated circuit output drivers without sacrificing switching frequency.

In accordance with the method of the invention, when a transmission line is to be driven to a particular state by a driver device, within an amount of time much less than the setup time for turning on the driver device, the voltage on predrive line that controls the driver device is quickly pulled to a level at or very near to the turn-on threshold voltage of the driver device. An impedance is then connected between an “on” voltage source that turns on the driver device and the predrive line to result in a desired controlled slope of the transmission line signal. Once the voltage level on the transmission line reaches a predetermined reference voltage level (e.g., the saturation voltage), the predrive line is quickly pulled to the “on” voltage level to finish out the transition.

### BRIEF DESCRIPTION OF THE DRAWING

The invention will be better understood from a reading of the following detailed description taken in conjunction with the drawing in which like reference designators are used to designate like elements, and in which:

FIG. 1 is a schematic block diagram of a conventional output driver;

FIG. 2A is a drain characteristics plot of a conventional NFET device;

FIG. 2B is a transfer characteristics plot of a conventional NFET device;

FIG. 3 is an operational flowchart of the method of the invention;

FIG. 4A is a schematic diagram of a preferred embodiment of an output buffer implemented in accordance with the invention;

FIG. 4B is a schematic diagram of an alternative embodiment of feedback circuit used in implementation of the output buffer of FIG. 4A; and

FIG. 5A is a waveform diagram illustrating a pulldown predriver signal in accordance with the invention; and

FIG. 5B is a waveform diagram illustrating a pullup predriver signal in accordance with the invention.

### DETAILED DESCRIPTION

A novel method and circuit for controlling the slew rate of output drivers is described in detail hereinafter. Although the invention is described in terms of specific illustrative embodiments, such as specific output driver designs, it is to be understood that the embodiments described herein are by way of example only and the scope of the invention is not intended to be limited thereby.

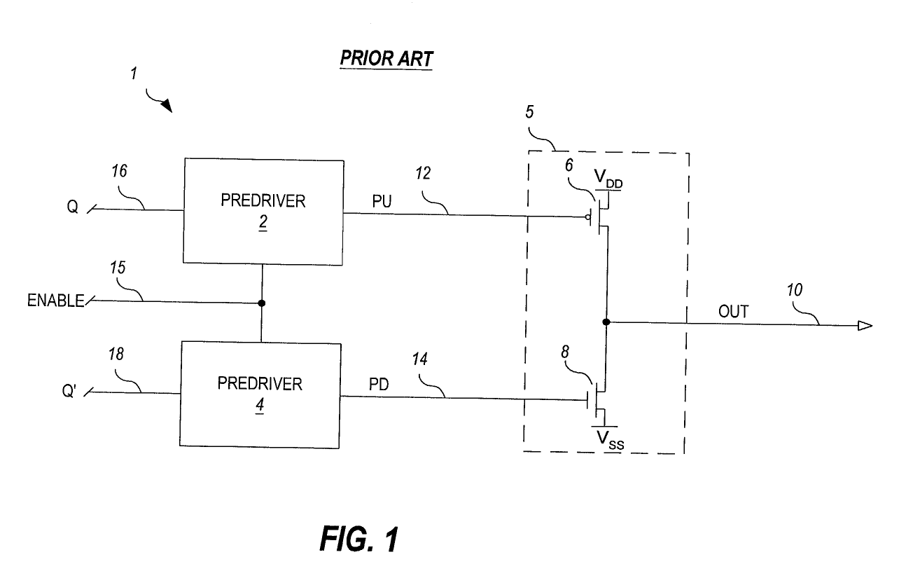

Turning now in detail to the drawing, FIG. 1 is a block diagram of a prior art output driver 1 configured to output a signal OUT on a transmission line 10. A driver circuit 5 is coupled to the transmission line 10. Driver circuit 5 comprises at least two switching devices 6, 8 that are used to connect the transmission line 10 to respective high and low voltage supplies V_{DD} and V_{SS}. The switching devices 6, 8 generally have terminals that allow the position of the switches 6, 8 to change and are connected to respective predriver circuits 2, 4, via respective lines 12, 14. Typically, the switching devices 6, 8 are implemented using a p-channel field effect transistor (PFET) and n-channel field effect transistor (NFET) respectively.

The input lines 16 and 18 of the predriver circuit 10 receive a differential signal Q, Q′, which is buffered to drive signal OUT on line 10 suitable for driving a heavily loaded output, and particularly useful as an off-chip output pad driver. The state of differential input signal Q, Q′, and an output enable signal ENABLE, is used to generate signals NPU and PD on the predrive output lines 12 and 14 respectively. Output enable signal ENABLE provides for a three-state output, including a high-impedance state (‘floating’), a logic high state (‘1’), and a logic low state (‘0’).

Predriver circuit 2 receives the logic signal Q and generates an associated pullup signal NPU on line 12 for driving the gate of the PFET 6 in the driver circuit 5. Pullup signal NPU is negative true in order to turn on the PFET 6 to electrically connect the transmission line 10 to the high voltage source V_{DD} to drive the output signal OUT to a logic high state.

Predriver circuit 4 similarly receives the complement logic signal Q′ and generates an associated pulldown signal PD for driving the gate of the NFET 8 in the driver circuit 5. Pulldown signal PD is positive true in order to turn on the NFET 8 to electrically connect the transmission line 10 to the low voltage source V_{SS} to drive the output signal OUT to a logic low state.

When disabled by output enable signal ENABLE, predriver circuits 2 and 4 disable their respective predriver circuits 2 and 4 such that their output signals NPU and PD do not track the input signals Q and Q′.

When the transmission line 10 is connected to one of the voltage sources V_{DD}, V_{SS}, the transmission line 10 is being “driven” by the driver circuit 5. Associated with the driving of the transmission line 10 is the charging time of the pullup and pulldown switching devices PFET 6 and NFET 8. The charging time as defined herein is the length of time required to turn on the pullup and pulldown switching devices 6 and 8 from a fully off state. In the illustrative embodiment, the charging time is the amount of time required cause the PFET 6 and NFET 8 to reach saturation from a fully off state.

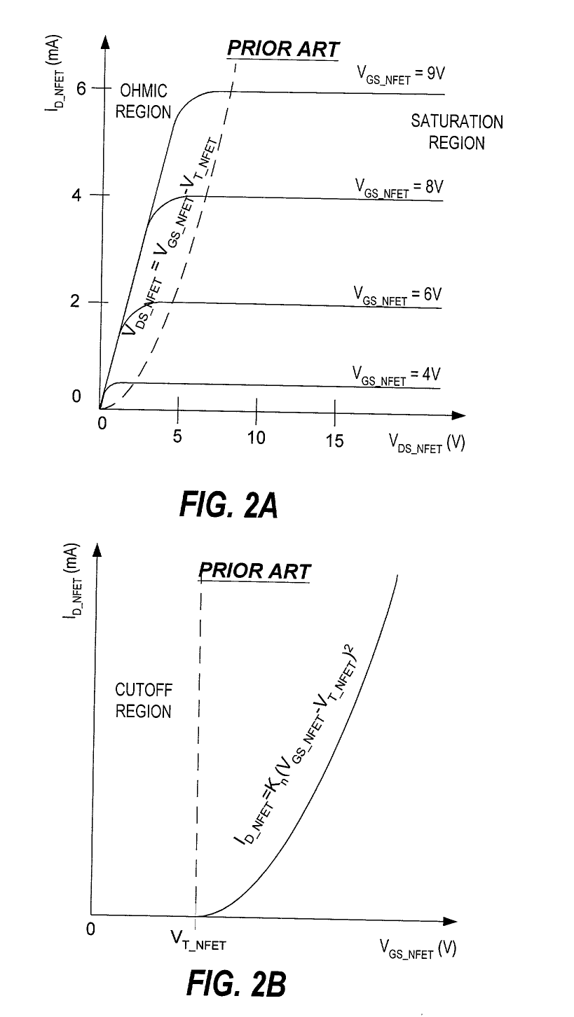

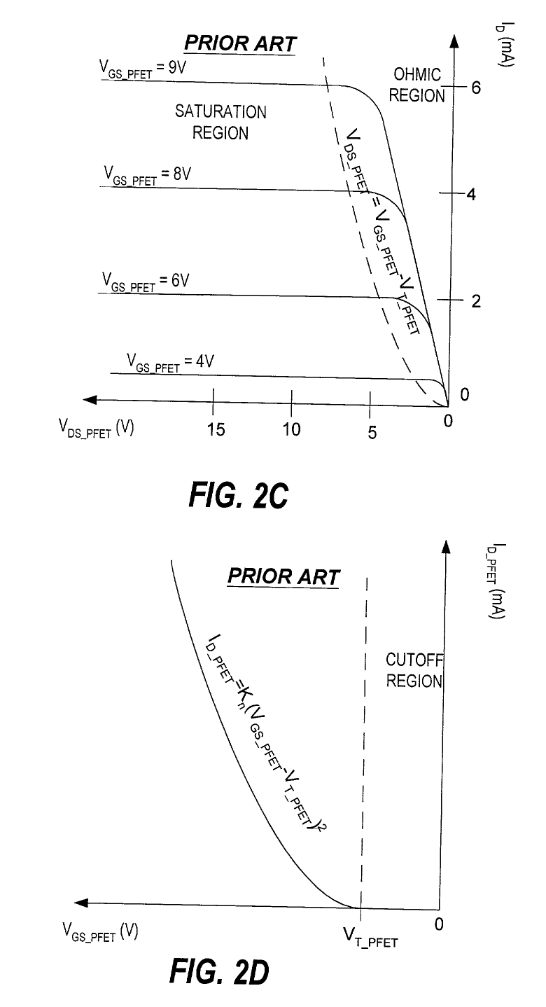

FIG. 2A is a drain characteristics plot and FIG. 2B is a transfer characteristics plot of a conventional NFET device. As illustrated, the conventional NFET operates in one of three regions according to the voltage V_{GS} applied at the gate. These regions are known as the “ohmic” or “linear” region, the “saturation” region, and the “cutoff” region.

FIG. 2A illustrates that in the linear region, the voltage seen at the drain V_{DS} is equal to the gate voltage V_{GS}_{_{—}}_{NFET} less the turn-on threshold voltage V_{T}_{_{—}}_{NFET} of the NFET device (i.e., V_{DS}_{_{—}}_{NFET}=V_{GS}_{_{—}}_{NFET}−V_{T}_{_{—}}_{NFET}). As illustrated in FIG. 2A, while the drain voltage V_{DS} is linear in this region, FIG. 2B illustrates that the drain current I_{D} in the linear region follows an exponential curve defined by I_{D}_{_{—}}_{NFET}=Kₙ(V_{GS}_{_{—}}_{NFET}−V_{T}_{_{—}}_{NFET})².

As further illustrated in FIG. 2A, when V_{DS}_{_{—}}_{NFET}≧V_{GS}_{_{—}}_{NFET}−V_{T}_{_{—}}_{NFET}, the drain current I_{D}_{_{—}}_{NFET} is constant, and the voltage V_{DS}_{_{—}}_{NFET} on the drain cannot increase due to the drain current I_{D}_{_{—}}_{NFET}. This region is known as the “saturation” region.

As illustrated in FIG. 2B, when V_{GS}_{_{—}}_{NFET} is less than the turn-on threshold voltage V_{T}_{_{—}}_{NFET} of the NFET device (i.e., V_{GS}_{_{—}}_{NFET}<V_{T}_{_{—}}_{NFET}), the drain current I_{D}_{_{—}}_{NFET} is zero (I_{D}_{_{—}}_{NFET}=0) and therefore the device is off. This region is known as the “cutoff” region. Because I_{D}_{_{—}}_{NFET}=0 until the gate voltage V_{GS}_{_{—}}_{NFET} reaches the turn-on threshold voltage V_{T}_{_{—}}_{NFET}, a setup time ΔT_{T}_{_{—}}_{NFET} elapses before the voltage V_{D}_{_{—}}_{NFET S} at the drain even begins to rise. The length of the setup time ΔT_{T}_{_{—}}_{NFET} depends on the value of the turn-on threshold voltage V_{T}_{_{—}}_{NFET} and strength of the devices driving the gate.

FIG. 2C is a drain characteristics plot and FIG. 2D is a transfer characteristics plot of a conventional PFET device. FIG. 2A illustrates that in the linear region, the voltage seen at the drain V_{DS}_{_{—}}_{PFET} is equal to the gate voltage V_{GS}_{_{—}}_{PFET} less the turn-on threshold voltage V_{T}_{_{—}}_{PFET} of the PFET device (i.e., V_{DS}_{_{—}}_{PFET}=V_{GS}_{_{—}}_{PFET}−V_{T}_{_{—}}_{PFET}). As illustrated in FIG. 2C, while the drain voltage V_{DS}_{_{—}}_{PFET} is linear in this region, FIG. 2D illustrates that the drain current I_{D}_{_{—}}_{PFET} in the linear region follows an exponential curve defined by I_{D}_{_{—}}_{PFET}=Kₙ(V_{GS}_{_{—}}_{PFET}−V_{T}_{_{—}}_{PFET})².

As further illustrated in FIG. 2C, when the PFET device is the “saturation” region, V_{DS}_{_{—}}_{PFET}≧V_{GS}_{_{—}}_{PFET}−V_{T}_{_{—}}_{PFET}, the drain current I_{D}_{_{—}}_{PFET} is constant, and the voltage V_{DS}_{_{—}}_{PFET} on the drain cannot increase due to the drain current I_{D}_{_{—}}_{PFET}.

As illustrated in FIG. 2D, the cutoff region occurs when V_{GS}_{_{—}}_{PFET} is less than the turn-on threshold voltage V_{T}_{_{—}}_{PFET} of the PFET device (i.e., V_{GS}_{_{—}}_{PFET}<V_{T}_{_{—}}_{PFET}), the drain current I_{D} is zero (I_{D}=0) and therefore the device is off. As with the NFET device discussed earlier, because I_{D}_{_{—}}_{PFET}=0 until the gate voltage V_{GS}_{_{—}}_{PFET} reaches the turn-on threshold voltage V_{T}_{_{—}}_{PFET}, a setup time ΔT_{T}_{_{—}}_{PFET} elapses before the voltage V_{DS}_{_{—}}_{PFET} at the drain even begins to rise. The length of the setup time ΔT_{T}_{_{—}}_{PFET} depends on the value of the turn-on threshold voltage V_{T}_{_{—}}_{PFET} and strength of the devices driving the gate.

Referring back to FIG. 1, the setup time ΔT_{T}_{_{—}}_{PFET}, ΔT_{T}_{_{—}}_{NFET} for turning on pullup PFET 6 and pulldown NFET 8 is essentially lost time since the devices 6, 8 do not even begin to turn on until a time ΔT_{T}_{_{—}}_{PFET}, ΔT_{T}_{_{—}}_{NFET} elapses to allow the respective voltage level of pullup signal PU on line 12 and pulldown signal PD on line 14 to reach their respective turn-on threshold voltages V_{T}_{_{—}}_{PFET}, V_{T}_{_{—}}_{NFET}. Depending on the size/strength of the pre-driver devices (not shown) and driver devices 6, 8, and the value of the turn-on threshold voltages V_{T}_{_{—}}_{PFET}, V_{T}_{_{—}}_{NFET} of driver devices 6, 8, the setup times V_{T}_{_{—}}_{PFET}, V_{T}_{_{—}}_{NFET} may be fairly lengthy. The invention utilizes this “lost” time to allow for a slower slew rate on the transmission line 10 without having to sacrifice signal speed.

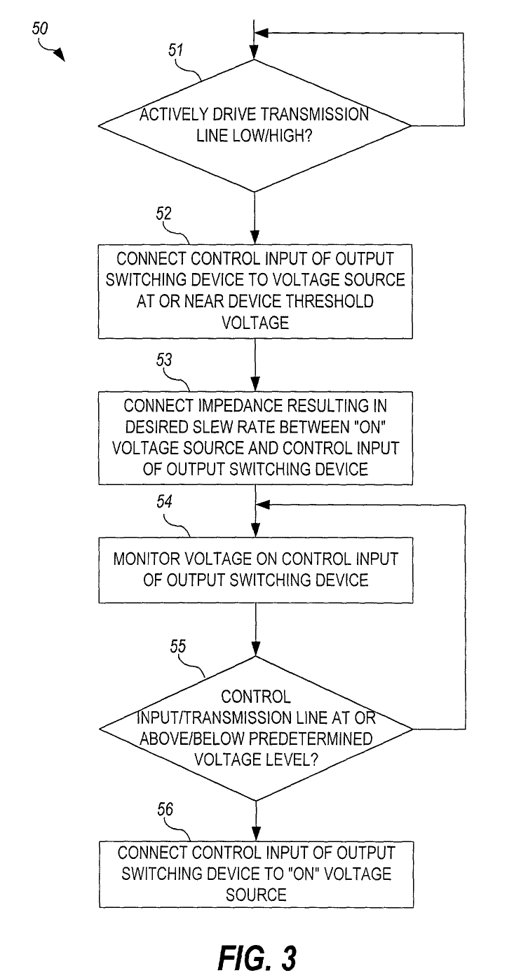

Turning now to FIG. 3, there is shown a flowchart illustrating the novel method 50 of the invention. As illustrated, when the transmission line signal is to be actively driven to a low/high state by an output switching device characterized by an “on” threshold voltage, as monitored in a step 51, a voltage source at or near the threshold voltage of the output switching device is connected 52 to the control input of the output switching device. This step 52 prepares the output switching device to turn on, avoiding the setup time ΔT_{T} latency caused by linearly ramping the charge on the control input of the output switching device.

Once the control input of the output switching device is at or near the threshold voltage of the output switching device, a predetermined impedance is connected 53 between the control input of the output switching device and an “on” voltage source which turns the output switching device to an “on” state. The “on” voltage source is a voltage source that generates a voltage level that, when connected to the control input of the output switching device, turn the output switching device to an “on” (i.e., fully conducting) state. The predetermined impedance is selected wuch that the predrive signal on the control input of the output switching device exhibits a linear voltage ramp of desired slope in the direction of the voltage level generated by the “on” voltage source. In the preferred embodiment, this is achieved via a plurality of programmed DACs configured to provide the desired “slow” ramp slope on the control input of the output switching device.

The voltage level on the control input of the output switching device is monitored 54. When the voltage level reaches a predetermined level (e.g., device saturation), as detected in step 55, the control input of the output switching device is connected 56 to the “on” voltage source.

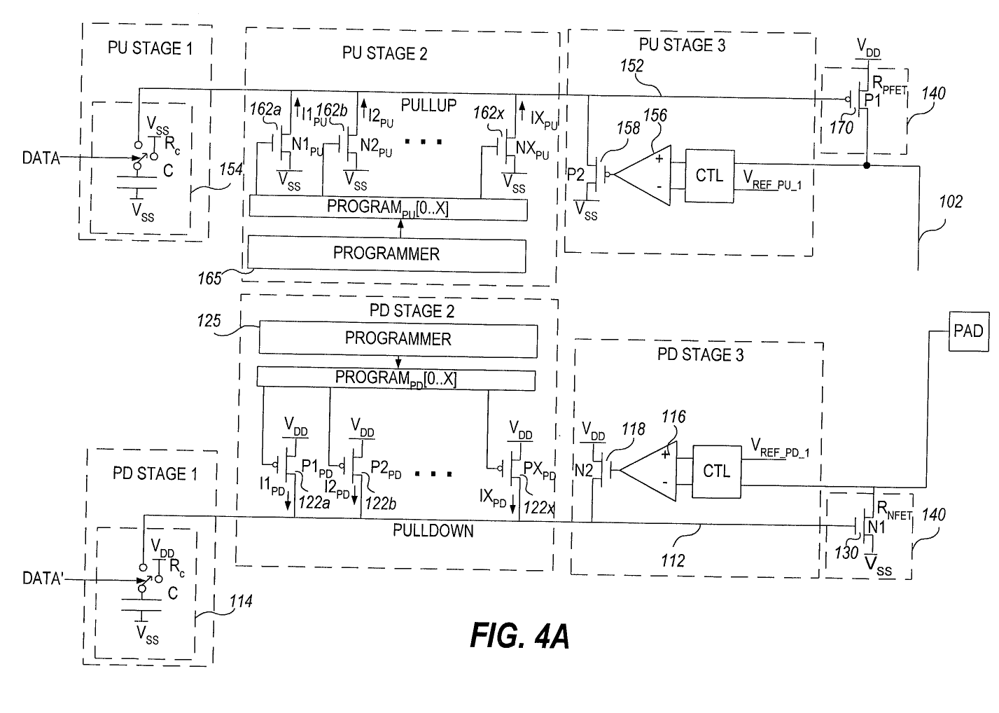

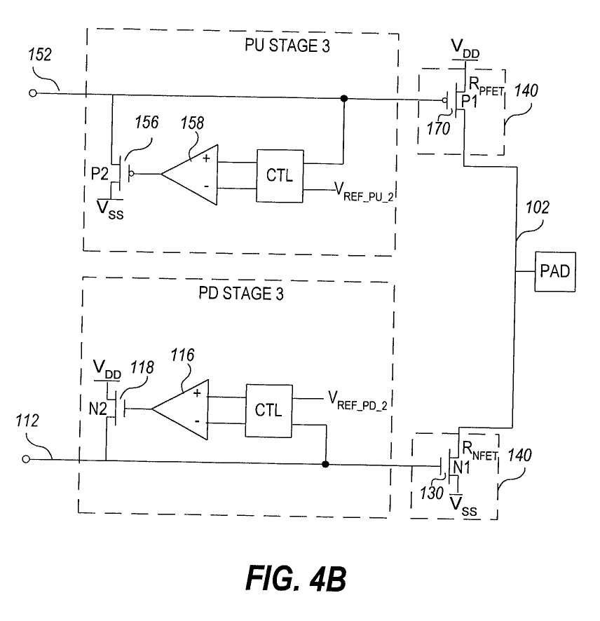

FIG. 4A is a schematic diagram of an exemplary embodiment of an output buffer 100 implemented in accordance with the invention. Output buffer 100 comprises a pulldown predriver circuit 110 which drives a pulldown circuit 140 and a pullup predriver circuit 150 which drives a pullup circuit 180. Pulldown circuit 140 is preferably implemented with an NFET device 130 having a turn-on threshold voltage V_{TH}_{_{—}}_{PD}. NFET device 130 has a source connected to a low voltage source V_{SS}, a drain connected to the transmission line 102, and a gate connected to receive a positive true predrive signal PULLDOWN on a pulldown predrive line 112. Pullup circuit 180 is preferably implemented using a PFET device 170 having a turn-on threshold voltage V_{TH}_{_{—}}_{PU}. PFET device 170 has a source connected to a high voltage source V_{DD}, a drain connected to the transmission line 102, and a gate connected to receive a negative true predrive signal NPULLUP on a pullup predrive line 152.

Pullup and pulldown predriver circuits 150 and 110 respectively receive a logic true signal DATA and its complement DATA′, whereby when logic signal DATA is in a high logic state, the transmission line 102 is driven to a high state, and when complement logic signal DATA′ is in a high state, the transmission line 102 is driven to a low state.

Each predriver circuit 110 and 150 is configured in three stages, PD STAGE 1, PD STAGE 2, PD STAGE 3, and PU STAGE 1, PU STAGE 2, PU STAGE 3, respectively.

Turning first to the pulldown predriver circuit 110, there is shown a first pulldown stage PD STAGE 1, a second pulldown stage PD STAGE 2, and a third pulldown stage PD STAGE 3. The first pulldown stage PD STAGE 1 comprises a switched capacitor 114 connected between the low voltage source V_{SS} and the pulldown predrive line 112 that controls the pulldown NFET device 130. Switched capacitor 114 is scaled in size such that the capacitance C charges the pulldown predrive line 112 to a voltage V_{S1}_{_{—}}_{PD} at or very near to the turn-on threshold voltage V_{TH}_{_{—}}_{PD} of pulldown NFET device 130 within a time T_{S1}_{_{—}}_{PD}. Time T_{S1}_{_{—}}_{PD} is an amount of time much less than the setup time ΔT_{T} for turning on pulldown NFET 130. In order to achieve T_{S1}_{_{—}}_{PD}<<ΔT_{T}_{_{—}}_{NFET}, the resistance R_{C} on the capacitor switch must be much less than the resistance of the pulldown NFET 130 (i.e., R_{C}<<R_{NFET}).

The second pulldown stage S2_{PD} comprises a plurality of resistive devices 122a, 122b, . . . , 122x, switchably connectable between a high voltage source V_{DD} and the pulldown predrive line 112. Preferably the plurality of resistive devices 122a, 122b, . . . , 122x are programmable via a programming circuit 125 which generates a programming word PROGRAM_{PD}[0 . . . X] with each bit 0 . . . X mapped to control the control input of a respective resistive device 122a, 122b, . . . , 122x. The values of the fixed or programmed resistances allow selection of a combination of devices to supply a preferred combined parallel resistance that results in a linear signal of a desired slope on pulldown predrive line 112.

The third pulldown stage S3_{PD} comprises a feedback circuit to monitor the voltae level on the transmission line 102 and to quickly pull the voltage on the transmission line 102 to the low state when it reaches a predetermined voltage level. In the preferred embodiment, third pulldown stage S3_{PD} comprises a comparator 116 having first input connected to the transmission line 102 and a second input connected to receive a pulldown reference signal V_{REF}_{_{—}}_{PD}. Comparator 116 has an output connected to feed the gate of a low-resistance NFET device 118 that is connected in drain-source relationship between the pulldown predrive line 112 and the high voltage source V_{DD}.

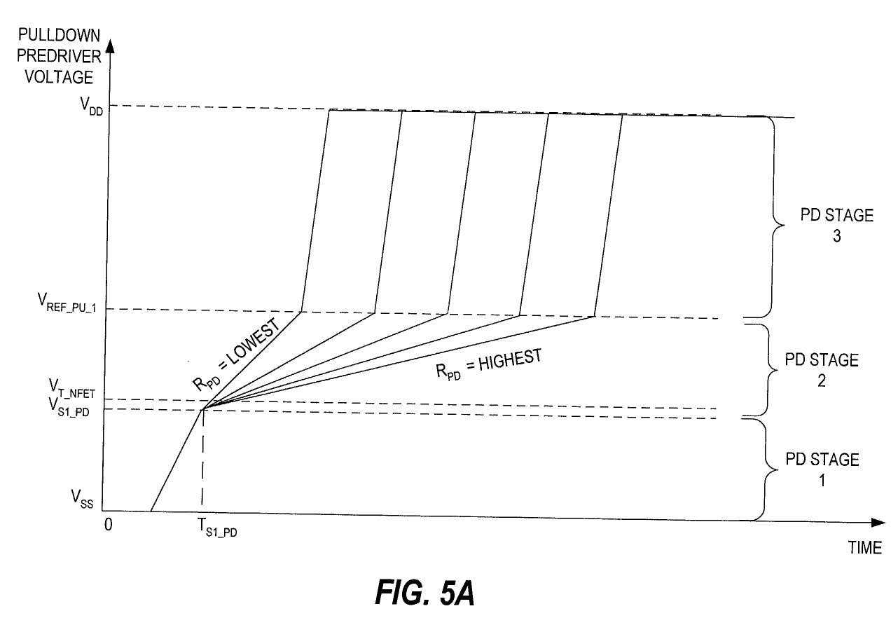

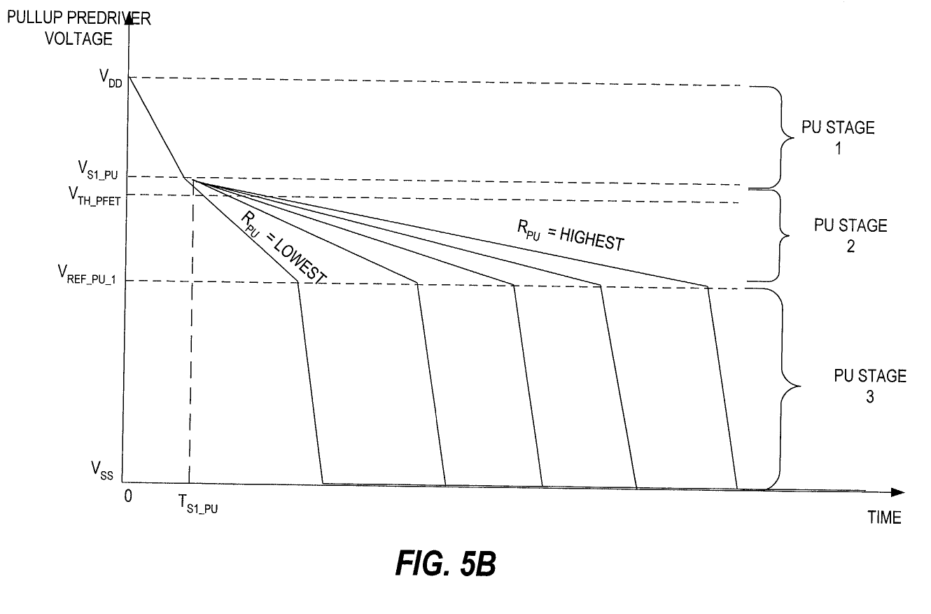

The operation of the pulldown predriver circuit 110 will now be discussed in conjunction with the signal diagram of FIG. 5A. When complementary logic signal DATA′ transitions to a high state, switched capacitor 114 is connected to pulldown predrive line 112. The connection allows current to flow through the capacitor 114, such that the charge stored in the capacitor 114 raises the voltage on pulldown predrive line 112 to a voltage V_{S1}_{_{—}}_{PD} at or very near the turn-on threshold voltage V_{TH}_{_{—}}_{PD} of pulldown NFET device 130 within a time T_{S1}_{_{—}}_{PD}. The resistance R_{C} of the switch is much less than the resistance of R_{NFET} of the pulldown NFET device 130 such that time T_{S1}_{_{—}}_{PD} is an amount of time much less than the setup time ΔT_{T} for turning on pulldown NFET 130.

Simultaneously, or within a short time thereafter, a selected combination of the plurality of resistive devices 122a, 122b, . . . , 122x, is connected between the high voltage source V_{SS} and the pulldown predrive line 112. The combined parallel resistance R_{PD} of the selected resistive devices results in a current flowing from high voltage source V_{DD} to the pulldown predrive line 112 to linearly ramp up the voltage on line 112 at a slope proportional to the amount of current flowing through the plurality of resistive devices 122a, 122b, . . . , 122x.

As illustrated in FIG. 5A where indicated by callout Stage 2, the higher the combined parallel impedance of the selected resistive devices 122a, 122b, . . . , 122x, the slower the slew rate (i.e., lower slope) of the signal transition. Significantly, the slew rate control of the pre-drive signal PD occurs in the linear region of the pulldown NFET device 130. In particular, the longer the amount of time the pulldown NFET device 130 spends in its linear region, the slower the slew rate of the signal output on the transmittion line 102 by pulldown NFET device 130 will be. This is achieved by slowing the slew rate of the pulldown predrive signal PULLDOWN seen on the control input of the driver NFET device 130. In other words, all slew rate control must happen while the pulldown NFET device is in its linear region.

For this reason, and since V_{DS}≧V_{GS}−V_{T}, once the voltage level on the pulldown predrive line 112 reaches V_{DS}≧V_{GS}−V_{T}=V_{REF}_{_{—}}_{PD}_{_{—}}₁, the pulldown NFET device 130 will have reached saturation. Stage 3 allows for quickly pulling the transmission line to the rail after reaching saturation in order to allow for the slowest slew rate without comprising switching speed. Accordingly, in operation, comparator 116 monitors the signal on the transmission line 110 and compares it to the reference signal V_{REF}_{_{—}}_{PD}_{_{—}}₁. If the voltage level on the predrive line 112 reaches V_{REF}_{_{—}}_{PD}_{_{—}}₁, the comparator 116 outputs a logic high on the gate of low-resistance NFET device 118. In turn, the NFET device 118 turns on and quickly pulls the voltage on the predrive line 112 to the V_{DD} rail.

In the alternative, as shown in FIG. 4B, comparator 116 has one input connected to the predrive line 112. Since V_{DS}≧V_{GS}−V_{T}, once the voltage level on the pulldown predrive line 112 reaches V_{GS}=V_{DS}+V_{T}=V_{REF}_{_{—}}_{PD}_{_{—}}₂, the pulldown NFET device will have reached saturation. In this embodiment, comparator 116 monitors the signal on the predrive line 112 and compares it to the reference signal V_{REF}_{_{—}}_{PD}_{_{—}}₂. If the voltage level on the predrive line 112 reaches V_{REF}_{_{—}}_{PD}_{_{—}}₂, the comparator 116 outputs a logic high on the gate of low-resistance NFET device 118. In turn, the NFET device 118 turns on and quickly pulls the voltage on the predrive line 112 to the V_{DD} rail.

FIG. 5A thus illustrates that after an elapse of time T_{S1}_{_{—}}_{PD} (much less than the setup time ΔT_{T}_{_{—}}_{NFET} for turning on pulldown NFET 130), the voltage on pulldown predrive line 112 is quickly charged to a level V_{S1}_{_{—}}_{PD} at or very near to the turn-on threshold voltage V_{T}_{_{—}}_{PD} of pulldown NFET device 130, as indicated by the callout Stage 1. An impedance is then connected between the high voltage source V_{DD} and the predrive line 112 to result in a controlled slope of the signal transition, as indicated by the callout Stage 2. Once the voltage level on the transmission line reaches a predetermined value V_{REF}_{_{—}}_{PU}_{_{—}}₁ (e.g., the saturation voltage), the predrive line 112 is quickly pulled to the high voltage level V_{DD}, as indicated by the callout Stage 3.

Turning now to the pullup predriver circuit 110, there is shown a first pullup stage PU STAGE 1, a second pullup stage PU STAGE 2, and a third pullup stage PU STAGE 3. The first pullup stage S1_{PU} comprises a switched capacitor 154 connected between one of either the pullup predrive line 114 or the low voltage source V_{SS}. 154 discharges the pullup predrive line 114 to a voltage V_{S1}_{_{—}}_{PU} at or very near to the turn-on threshold voltage V_{T}_{_{—}}_{PFET} of pullup PFET device 170 within a time T_{S1}_{_{—}}_{PU}. Time T_{S1}_{_{—}}_{PU} is an amount of time much less than the setup time ΔT_{T}_{_{—}}_{PFET} for turning on pullup PFET 170. In order to achieve T_{S1}_{_{—}}_{PU}<<ΔT_{T}_{_{—}}_{PFET}, the resistance R_{C} of the switch of the switched capacitor 154 must be much less than the resistance of the pullup PFET 170 (i.e., R_{C}<<R_{PFET}).

The second pullup stage PU STAGE 2 comprises a plurality of resistive devices 162a, 162b, . . . , 162x, switchably connectable between the low voltage source V_{SS} and the pullup predrive line 152. Preferably the plurality of resistive devices 162a, 162b, . . . , 162x are programmable to via a programming circuit 165 which generates a programming word PROGRAM_{PU}[0 . . . X] with each bit 0 . . . X mapped to control the control input of a respective resistive device 162a, 162b, . . . , 162x. The values of the fixed or programmed resistances allow selection of a combination of devices to supply a preferred combined parallel resistance that results in a linear signal of a desired slope on pullup predrive line 152.

The third pullup stage PU STAGE 3 comprises a comparator 156 having first input connected to the transmission line 102 and a second input connected to receive a pullup reference signal V_{REF}_{_{—}}_{PU}, and an output connected to feed the gate of a low-resistance PFET device 158 that is connected in drain-source relationship between the pullup predrive line 152 and the low voltage source V_{DD}.

FIG. 5B illustrates that the pullup predriver circuit 150 operates similarly to that of the pulldown predriver circuit 110. Briefly, switched capacitor 154 is responsive to logic signal DATA to connect the capacitor the pullup predrive line 152 when logic signal DATA transitions to a high state. This connection allows the pullup predrive line 152 to discharge to lower the voltage on pulldown predrive line 112 to a voltage V_{S1}_{_{—}}_{PU} at or very near the turn-on threshold voltage V_{T}_{_{—}}_{PFET} of pullup PFET device 170 within a time T_{S1}_{_{—}}_{PU} much less than the setup time ΔT_{T}_{_{—}}_{PFET} for turning on pullup PFET 170.

Simultaneously, or within a short time thereafter, a selected combination of the plurality of resistive devices 162a, 162b, . . . , 162x, is connected between the low voltage source V_{SS} and the pullup predrive line 152. The combined parallel resistance R_{PU} of the selected resistive devices results in a linear ramp down of the voltage on line 152 at a slope proportional to the amount of current flowing through the plurality of resistive devices 162a, 162b, . . . , 162x.

Comparator 156 monitors the signal on the transmission line 110 and compares it to the reference signal V_{REF}_{_{—}}_{PU}_{_{—}}₁. If the voltage level on the predrive line 152 reaches V_{REF}_{_{—}}_{PU}_{_{—}}₁, the comparator 156 outputs a logic low on the gate of low-resistance PFET device 158. In turn, the PFET device 158 turns on and quickly pulls the voltage on the predrive line 152 to the V_{SS} rail.

Alternatively, the comparator 156 could have one input connected to the predrive line 152, and if the voltage level on the predrive line 152 reaches a voltage V_{REF}_{_{—}}_{PU}_{_{—}}₂, the comparator 156 outputs a logic low to turn on PFET 158.

The invention provides several advantages over the prior art. In particular, the invention utilizes previously “lost” setup time to expand the slew rate window to allow slower slew rates without changing the signal frequency. Second, by quickly pulling the signal to the rail once the driver device reaches saturation, further expansion to the slew rate window is achieved.

While illustrative and presently preferred embodiments of the invention have been described in detail herein, it is to be understood that the inventive concepts may be otherwise variously embodied and employed and that the appended claims are intended to be construed to include such variations except insofar as limited by the prior art.

What is claimed is:

1. A method for reducing the slew rate of a signal on a transmission line driven by an output switching device, said output switching device characterized by a turn-on threshold voltage and comprising a control input responsive to a predrive signal for placing said output switching device in one of an OFF state, a linear state, or an ON state, wherein: said output switching device is in said OFF state not driving said transmission line when said predrive signal is at a voltage level between said turn-on threshold voltage and an OFF voltage level; said output switching device is in a linear state driving said transmission line to a voltage level proportional to said predrive signal when said predrive signal is at a voltage level between said turn-on threshold voltage and a saturation voltage level; and said output switching device is in said ON state driving said transmission line to predetermined constant voltage level when said predrive signal is at a voltage level between said saturation voltage level and said ON voltage level, said method comprising:
connecting the control input of said output switching device to a voltage source at or near said turn-on threshold voltage;
connecting a predetermined impedance between an ON voltage source producing said ON voltage level and said control input of said output switching device;
monitoring a voltage level on at least one of said control input of said output switching device and said transmission line; and
if said monitored voltage level reaches a predetermined reference voltage, connecting said control input of said output switching device to said ON voltage source.

2. An apparatus for reducing the slew rate of signal on a transmission line of an integrated circuit, comprising:
an output switching device characterized by an output switching resistance and a turn-on threshold voltage, said output switching device having a control input responsive to a predrive signal for placing said output switching device in one of an OFF state, a linear state, or an ON state, wherein: said output switching device is in said OFF state not driving said transmission line when said predrive signal is at a voltage level between said turn-on threshold voltage and an OFF voltage level; said output switching device is in a linear state driving said transmission line to a voltage level proportional to said predrive signal when said predrive signal is at a voltage level between said turn-on threshold voltage and a saturation voltage level; and said output switching device is in said ON state driving said transmission line to predetermined constant voltage level when said predrive signal is at a voltage level between said saturation voltage level and said ON voltage level;
a first predrive stage which connects the control input of said output switching device to a voltage source at or near said turn-on threshold voltage;
a second predrive stage which connects a predetermined impedance between an ON voltage source producing said ON voltage level and said control input of said output switching device;
a third predrive stage which monitors a voltage level on at least one of said control input of said output switching device and said transmission line; and if said monitored voltage level reaches a predetermined reference voltage, connects said control input of said output switching device to said ON voltage source.

3. An apparatus in accordance with claim 2, wherein:
said first predrive stage comprises a switch capacitor switchable to connect a capacitor between said control input of said output switching device, said capacitor sized to drive said control input of said output switching device to a voltage level at or near said turn-on threshold voltage and characterized by a smaller switching resistance than said output switching resistance of said output switching device.

4. An apparatus in accordance with claim 2, wherein:
said second predrive stage comprises a plurality of resistive devices switchably connectable between said control line and said ON voltage source.

5. An apparatus in accordance with claim 4, wherein:
said second predrive stage comprises a programming circuit responsive to a programmed value mapped to said predetermined impedance to switchably connect zero or more of said plurality of resistive devices between said control line and said ON voltage source, said connected zero or more of said plurality of resistive devices having a combined parallel impedance equal to said predetermined impedance.

6. An apparatus in accordance with claim 4, wherein said plurality of resistive devices comprise resistors.

7. An apparatus in accordance with claim 4, wherein said plurality of resistive devices comprise field effect transistors (FETs).

8. An apparatus in accordance with claim 2, wherein:
said third predrive stage comprises a comparator having a first input connected to said transmission line and a second input connected to receive said reference voltage and generating a comparator output signal indicating whether or not a voltage level on said transmission line has reached said reference voltage; and
a switch device responsive to said comparator output signal which connects said control input of said output switching device to said ON voltage source when said comparator output signal indicates that the voltage level on said transmission line has reached said reference voltage.

9. An apparatus in accordance with claim 2, wherein:
said third predrive stage comprises a comparator having a first input connected to said control input of said output switching device and a second input connected to receive said reference voltage and generating a comparator output signal indicating whether or not a voltage level on said transmission line has reached said reference voltage; and
a switch device responsive to said comparator output signal which connects said control input of said output switching device to said ON voltage source when said comparator output signal indicates that the voltage level on said control input has reached said reference voltage.
